(19) United States
(12) Patent Application Publication
(10) Pub. No.: US 2026/0047184 A1
(43) Pub. Date: Feb. 12, 2026

(54) METAL-INSULATOR-METAL CAPACITOR STRUCTURE, INTEGRATED CIRCUIT, AND METHOD FOR FORMING METAL-INSULATOR-METAL CAPACITOR STRUCTURE

(71) Applicant: Taiwan Semiconductor Manufacturing Company, Ltd., Hsinchu (TW)

(72) Inventors: Sin-I Du, Hsinchu County (TW); Chih-Pin Hung, Hsinchu City (TW); Hung-Han Lin, Hsinchu City (TW); Wei-Han Lee, Hsinchu City (TW); Cheng Hao Liu, Taoyuan City (TW)

(73) Assignee: Taiwan Semiconductor Manufacturing Company, Ltd., Hsinchu (TW)

(21) Appl. No.: 18/798,840

(22) Filed: Aug. 9, 2024

(51) Int. Cl. H01L 27/08; H01L 23/528

(52) U.S. Cl. CPC H10D 84/212; H01L 23/5283; H01L 23/5286; H10D 1/042; H10D 1/714

(57) ABSTRACT

A Metal-Insulator-Metal (MIM) capacitor structure is provided. The MIM capacitor structure includes a first MIM capacitor, a second MIM capacitor, and a connection structure. In response to an increment of a positive bias voltage, a first capacitance of the first MIM capacitor increases. In response to the increment of the positive bias voltage, a second capacitance of the second MIM capacitor decreases. The connection structure is configured to electrically couple the first MIM capacitor and the second MIM capacitor in parallel or in series.

### BACKGROUND

A capacitor is a fundamental component in electronic circuits, serving a multitude of crucial functions. The capacitor may store electrical energy in an electric field, which may be used to smooth out a voltage fluctuation, couple and decouple a signal, create a resonant circuit, implement a timing circuit, or recover energy in an inductive load. The ability to manipulate and control electrical signals makes the capacitor indispensable in a vast array of electronic devices, such as power supplies, filters, oscillators . . . etc.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to 1C are schematic diagrams of the capacitance change with direct current (DC) bias voltage for various capacitors according to some embodiments of the disclosure.

FIG. 1D to 1F are schematic diagrams of the gain ratio change with alternating current (AC) voltage for various capacitors according to some embodiments of the disclosure.

FIG. 2A is a schematic top view of a Metal-Insulator-Metal (MIM) capacitor according to one embodiment of the disclosure.

FIG. 2B and FIG. 2C are a schematic top view and a schematic cross-section view of a MIM capacitor according to one embodiment of the disclosure.

FIG. 2D and FIG. 2E are schematic top views of two MIM capacitor array according to two embodiments of the disclosure.

FIG. 3A is a schematic cross-section view of a MIM capacitor disposed on a substrate according to one embodiment of the disclosure.

FIG. 3B and FIG. 3C are schematic cross-section views of two MIM capacitors disposed on a substrate according to two embodiments of the disclosure.

FIG. 4A to FIG. 4F are schematic cross-section views of two MIM capacitors disposed on two substrates according to some embodiment of the disclosure.

FIG. 5A to FIG. 5B are schematic cross-section views of a MIM capacitor according to two embodiments of the disclosure.

FIG. 6A to FIG. 6E are schematic layouts of a MIM capacitor circuit according to some embodiments of the disclosure.

FIG. 7 is a schematic flowchart of a method for forming a MIM capacitor structure according to some embodiments of the disclosure.

### DETAILED DESCRIPTION

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as “comprise” and “include” are open-ended terms, and should be explained as “including but not limited to . . . ”.

The term “coupling (or connection)” used throughout the whole specification of the present application (including the appended claims) may refer to any direct or indirect connection means. For example, if the text describes that a first device is coupled (or connected) to a second device, it should be interpreted that the first device may be directly connected to the second device, or the first device may be indirectly connected through other devices or certain connection means to be connected to the second device. The terms “first”, “second”, and similar terms mentioned throughout the whole specification of the present application (including the appended claims) are merely used to name discrete elements or to differentiate among different embodiments or ranges. Therefore, the terms should not be regarded as limiting an upper limit or a lower limit of the quantity of the elements and should not be used to limit the arrangement sequence of elements. In addition, wherever possible, elements/components/steps using the same reference numerals in the drawings and the embodiments represent the same or similar parts. Reference may be mutually made to related descriptions of elements/components/steps using the same reference numerals or using the same terms in different embodiments.

It should be noted that in the following embodiments, the technical features of several different embodiments may be replaced, recombined, and mixed without departing from the spirit of the disclosure to complete other embodiments. As long as the features of each embodiment do not violate the spirit of the disclosure or conflict with each other, they may be mixed and used together arbitrarily.

Metal-Insulator-Metal (MIM) capacitors are compact, high-capacitance components with low equivalent series resistances, ideal for high-frequency and high-density circuits. In order to make sure capacitances do not change obviously with respect to a direct current (DC) bias voltage, traditional MIM capacitor structures that aim for a low voltage coefficient of capacitance (VCC) often compromise on capacitance density. Further, traditional MIM capacitor structures are unable to modify capacitances. Moreover, when the traditional capacitors are used to form a filter, the fabrication of the traditional capacitors may require the use of additional photomasks, and the capacitance value and capacitance density of the traditional capacitors are limited by the complexity of the structure and the possibility of process variation during fabrication.

In addition, insufficient capacitance resulting from the bias voltage characteristic of the traditional capacitors may lead to signal distortion. For example, if a gain of a filter varies with the value of the bias voltage, it may cause distortion or offset in the output signal. This is because the change in bias voltage may cause a change in the frequency response of the filter, resulting in a change in the frequency components of the output signal. Therefore, it is the pursuit of people skilled in the art to provide a novel structure of the MIM capacitor.

This disclosure proposed a novel high/low/band pass filter with an adjustable MIM capacitor structure, which provides high capacitance density while almost completely mitigating capacitance variation caused by voltage bias by a novel structure arrangement. This design prevents distortion or offset of output signals and provides variable capacitance. Specifically, two specific MIM capacitors may be electrically coupled together through wafer bonding to form a MIM capacitor structure. Therefore, no additional mask is not required for the fabrication of the MIM capacitor structure.

Further, the DC bias characteristic of the MIM capacitor structure is adjustable through changing the material of the two MIM capacitors. In this manner, The MIM capacitors used in a filter may have the characteristic of low VCC and high capacitance density, preventing distortion or offset of the output signal and provide adjustable capacitance. Further details of the MIM capacitor structure will be discussed below with respect to the accompanying drawings.

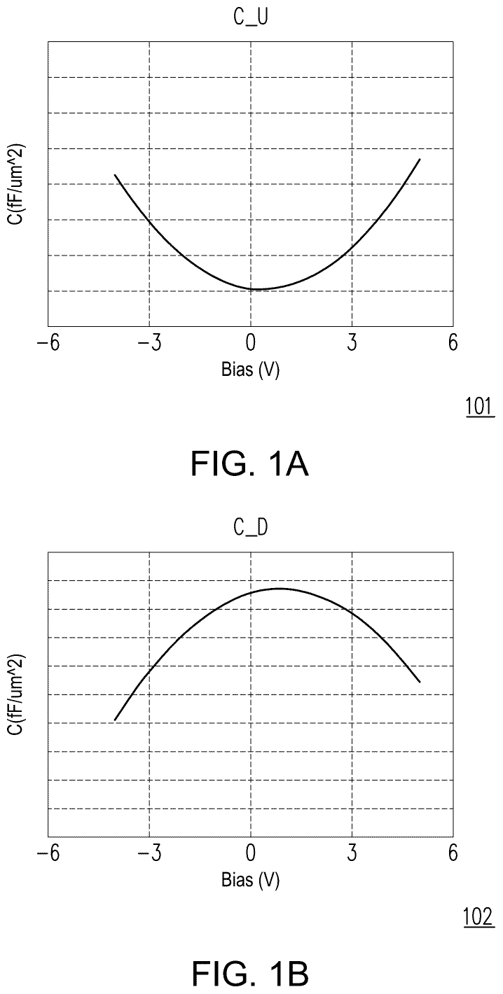

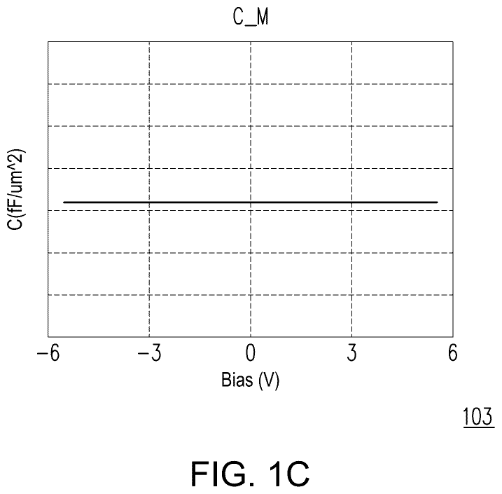

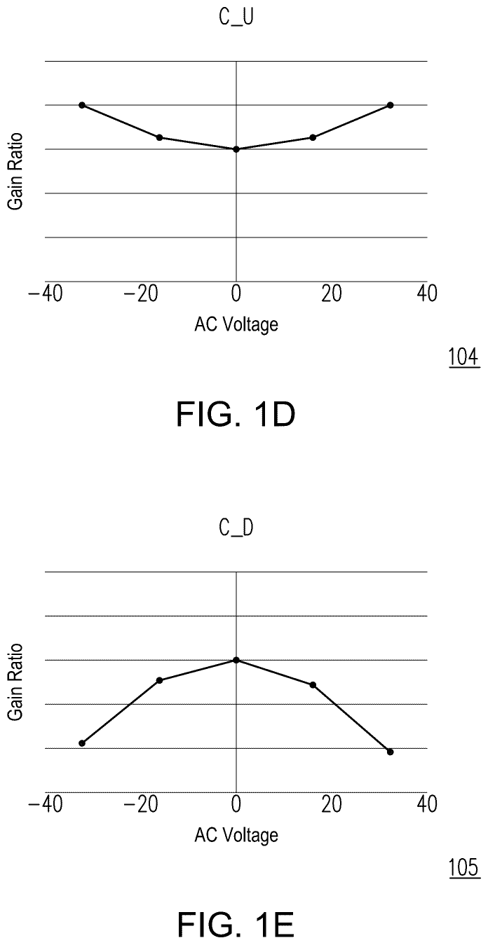

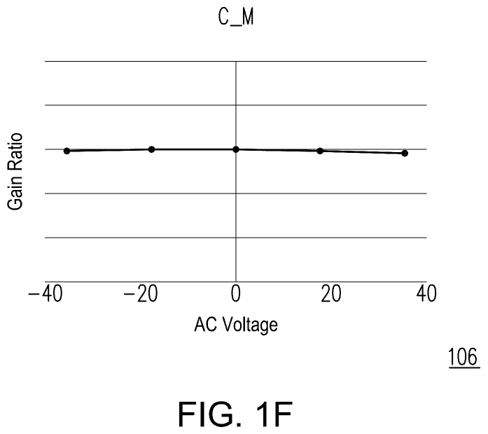

FIG. 1A to 1C are schematic diagrams of the capacitance change with DC bias voltage for various capacitors according to some embodiments of the disclosure.

Reference is made to FIG. 1A first. A diagram 101 depicts the capacitance-voltage characteristic of a first type of MIM capacitor. As shown in FIG. 1A, a minimum capacitance of the first type of MIM capacitor occurs when the bias voltage may be close to zero or a small voltage. That is, as the bias voltage starts to deviate from zero or the small voltage, the capacitance of the first type of MIM capacitor may increase regardless of whether the bias voltage is increasing or decreasing.

Reference is made to FIG. 1B now. A diagram 102 depicts the capacitance-voltage characteristic of a second type of MIM capacitor. As shown in FIG. 1B, a maximum capacitance of the second type of MIM capacitor occurs when the bias voltage may be close to zero or a small voltage. That is, as the bias voltage starts to deviate from zero or the small voltage, the capacitance of the second type of MIM capacitor may decrease regardless of whether the bias voltage is increasing or decreasing.

Reference is now made to FIG. 1A and FIG. 1B together. The capacitance of both the first type of MIM capacitor and the second type of MIM capacitor varies with the bias voltage. That is, if a signal is input to either the first type of MIM capacitor or the second type of MIM capacitor, different output results may be obtained under different bias voltages. In other words, the first type of MIM capacitor and the second type of MIM capacitor may cause distortion or offset of the output signal in a circuit.

It is noted that, the voltage-capacitance characteristic of the first type of MIM capacitor exhibits an upward curve. Therefore, the first type of MIM capacitor may be referred to as a first MIM capacitor C_U. On the other hand, the voltage-capacitance characteristic of the second type of MIM capacitor exhibits a downward curve. Therefore, the second type of MIM capacitor may be referred to as a second MIM capacitor C_D.

Reference is now made to FIG. 1C. A diagram 103 depicts the capacitance-voltage characteristic of a third MIM capacitor C_M. It is worth mentioned that, by merging the upward curve of the voltage-capacitance characteristic of the first MIM capacitor C_U with the downward curve of the voltage-capacitance characteristic of the second MIM capacitor C_D, a substantially flat horizontal line as shown in the diagram 103 may be obtained. That is, changes in bias voltage do not affect the capacitance of the merged result. In other words, in response to the increment of the positive bias voltage, a total capacitance of a MIM capacitor structure forming by the first MIM capacitor C_U and the second MIM capacitor C_D may substantially remain a fixed value. Therefore, the distortion of the signal may be prevented.

In other words, by merging the first MIM capacitor C_U and the second MIM capacitor C_D, the third MIM capacitor C_M with a mixed voltage-capacitance characteristic of the first capacitor C_U and the second capacitor C_D may be obtained. In one embodiment, the first MIM capacitor C_U and the second MIM capacitor C_D may be electrically coupled together in parallel or in series to form the MIM capacitor structure as the third MIM capacitor C_M. However, this disclosure is not limited thereto.

It is worth mentioned that, a voltage coefficient of capacitance may be used to represent a voltage-capacitance characteristic of a capacitor. Further, voltage-capacitance characteristic of a MIM capacitor may be determined based on a material of a capacitor dielectric (may be also called as the capacitor insulator) disposed between a top metal electrode and a bottom metal electrode. That is, a capacitor may be determined as the first MIM capacitor C_U or the second MIM capacitor C_D based on the material of the capacitor dielectric. For example, according to experiment results, the material of the capacitor dielectric of the first MIM capacitor C_U may include silicon nitride (SiN), or high k dielectric films formed by atomic layer deposition (ALD) with zirconium oxide (ZrO2)/hafnium oxide (HfO2)/zirconium oxide (ZrO2) or zirconium oxide (ZrO2)/aluminum oxide (Al2O3)/zirconium trioxide (ZrO3). On the other hand, according to experiment results, the material of the capacitor dielectric of the second MIM capacitor C_D may include silicon oxide (SiO2), or barium titanium oxide (BaTiO3). In addition, the material of the top metal electrode or the bottom metal electrode may include poly-silicon (Poly-Si) , silicon (Si), titanium (Ti), tantalum (Ta), aluminum (Al), tungsten (W), zinc (Zn), indium (In), gallium (Ga), germanium (Ge), or carbon (C). However, this disclosure is not limited thereto.

FIG. 1D to 1F are schematic diagrams of the gain ratio change with AC voltage for various capacitors according to some embodiments of the disclosure.

Reference is made to FIG. 1D first. A diagram 104 depicts the gain-voltage characteristic of the first MIM capacitor C_U. As shown in FIG. 1D, a minimum gain ratio of the first MIM capacitor C_U occurs when the AC voltage may be close to zero. That is, as the AC voltage starts to deviate from zero, the capacitance of the first MIM capacitor C_U may increase regardless of whether the AC voltage is increasing or decreasing.

Reference is made to FIG. 1E first. A diagram 105 depicts the gain-voltage characteristic of the second MIM capacitor C_D. As shown in FIG. 1D, a maximum gain ratio of the second MIM capacitor C_D occurs when the AC voltage may be close to zero. That is, as the AC voltage starts to deviate from zero, the capacitance of the second MIM capacitor C_D may increase regardless of whether the AC voltage is increasing or decreasing.

Reference is now made to FIG. 1D and FIG. 1E together. The capacitance of both the first MIM capacitor C_U and the second of MIM capacitor C_D varies with the AC voltage. That is, if a signal is input to either the first MIM capacitor C_U or the second MIM capacitor C_D, different output results may be obtained under different AC voltages. This is because the change in bias voltage may cause a change in the frequency response, resulting in a change in the frequency components of the output signal. In other words, the first MIM capacitor C_U and the second MIM capacitor C_D may cause distortion or offset of the output signal in a circuit.

Reference is now made to FIG. 1F. A diagram 106 depicts the gain-voltage characteristic of the third MIM capacitor C_M under AC voltages. It is worth mentioned that, by merging the upward curve of the gain-capacitance characteristic of the first MIM capacitor C_U with the downward curve of the gain-capacitance characteristic of the second MIM capacitor C_D, a substantially flat horizontal line as shown in the diagram 106 may be obtained. That is, changes in AC voltage do not affect the gain ratio of the merged result. Therefore, the distortion of the signal may be prevented.

In short, the first MIM capacitor C_U may be obtained or determined based on a material of a capacitor dielectric. The voltage-capacitance characteristic of the first MIM capacitor C_U may exhibit an upward curve with a minimum capacitance at 0V or a small voltage. That is, in response to an increment of a positive bias voltage, a first capacitance of the first MIM capacitor C_U may increase. Further, the second MIM capacitor C_D may be obtained or determined based on a material of a capacitor dielectric. The voltage-capacitance characteristic of the second MIM capacitor C_D may exhibit a downward curve with a maximum capacitance at 0V or a small voltage. That is, in response to an increment of a positive bias voltage, a second capacitance of the second MIM capacitor C_D may decrease. Furthermore, a connection structure may be configured to electrically coupling the first MIM capacitor and the second MIM capacitor in parallel or in series. In this manner, the distortion of the signal may be prevented.

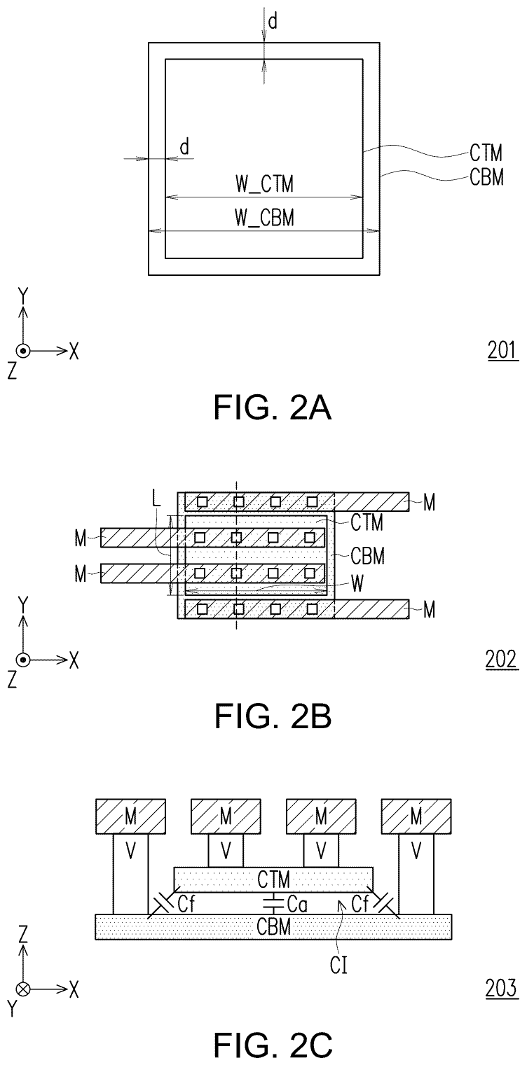

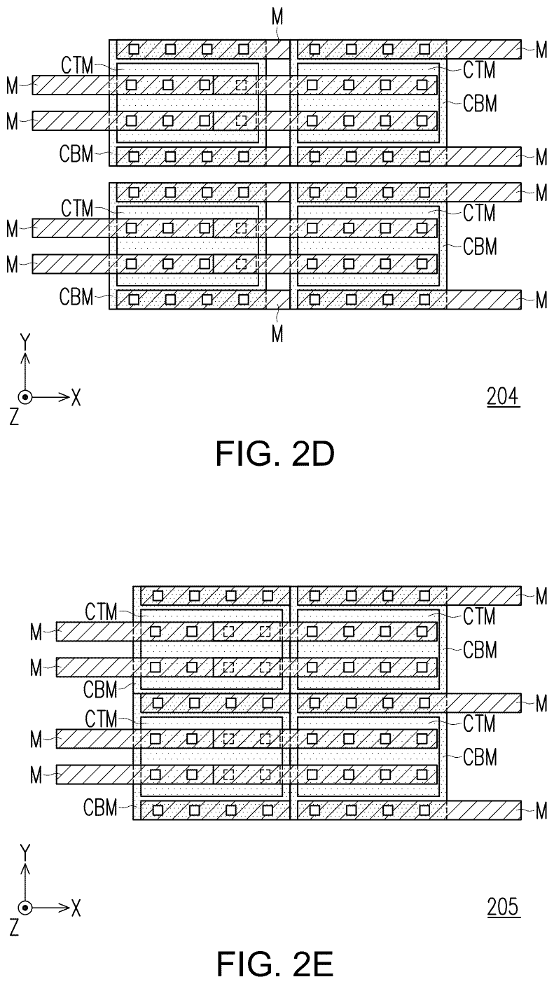

FIG. 2A is a schematic top view of a Metal-Insulator-Metal (MIM) capacitor according to one embodiment of the disclosure.

With reference to FIG. 2A, a top view 201 depicts a MIM capacitor. The MIM capacitor may include a top metal electrode CTM and a bottom metal electrode CBM separated by a capacitor dielectric layer (not shown). According to design rules and experiment results, the bottom metal electrode CBM may be arranged under the top metal electrode CTM and the capacitor dielectric layer. Further, the bottom metal electrode CBM may have a larger footprint than the top metal electrode CTM. That is, a bottom width W_CBM may be larger than a top width W_CTM. In one embodiment, both the bottom metal electrode CBM and the top metal electrode CTM may be rectangular, and from a top view, each boundary of the bottom metal electrode CBM is at least a threshold distance d away from each boundary of the top metal electrode CTM. For example, the threshold distance d may be 0.1 to 1 micron. However, this disclosure is not limited thereto.

FIG. 2B and FIG. 2C are a schematic top view and a schematic cross-section view of a MIM capacitor according to one embodiment of the disclosure.

Reference is made to FIG. 2B first. A top view 202 depicts one embodiment of a layout of a MIM capacitor. The top metal electrode CTM and the bottom metal electrode CBM may be respectively coupled to at least one metal track M. The metal track M may be configured to receive a bias voltage or a ground voltage according to design needs. Further, the top metal electrode CTM may have a width W and a length L, and the width W and the length L may be both smaller that a side length of the bottom metal length CBM.

Reference is made to FIG. 2C now. A cross-section view 203 depicts one embodiment of the layout of the MIM capacitor. The top metal electrode CTM and the bottom metal electrode CBM may be respectively coupled to at least one via V. The via may be further electrically coupled to the metal track M. Further, an insulator CI may be disposed between the top metal electrode CTM and the bottom metal electrode CBM as the capacitor dielectric of the MIM capacitor. Furthermore, based on the geometries of the top metal electrode CTM and the bottom metal electrode CBM and the property of the dielectric material of the insulator CI, an area capacitance of the MIM capacitor may be determined. Moreover, parasitic capacitance of the MIM capacitor may be determined as at least one fringe capacitance CF. However, this disclosure is not limited thereto.

FIG. 2D and FIG. 2E are schematic top views of two MIM capacitor array according to two embodiments of the disclosure.

Reference is made to FIG. 2D first. A top view 204 depicts one embodiment of a layout of a MIM capacitor array. As shown in FIG. 2D, the MIM capacitor array may include 4 MIM capacitors. Each MIM capacitor may include its own isolated top metal electrode CTM and bottom metal electrode CBM. Each top metal electrode CTM and each bottom metal electrode CBM may be electrically coupled to at least one metal track M, respectively. Therefore, this type of layout may be referred to as “Isolated CBM layout”.

Reference is made to FIG. 2E now. A top view 205 depicts one embodiment of a layout of a MIM capacitor array. As shown in FIG. 2E, the MIM capacitor array may include 4 MIM capacitors. Each MIM capacitor may include its own isolated top metal electrode CTM, but each MIM capacitor may share one signal bottom metal electrode CBM. Each top metal electrode CTM and the shared bottom metal electrode CBM may be electrically coupled to at least one metal track M, respectively. Therefore, this type of layout may be referred to as “Common CBM layout”.

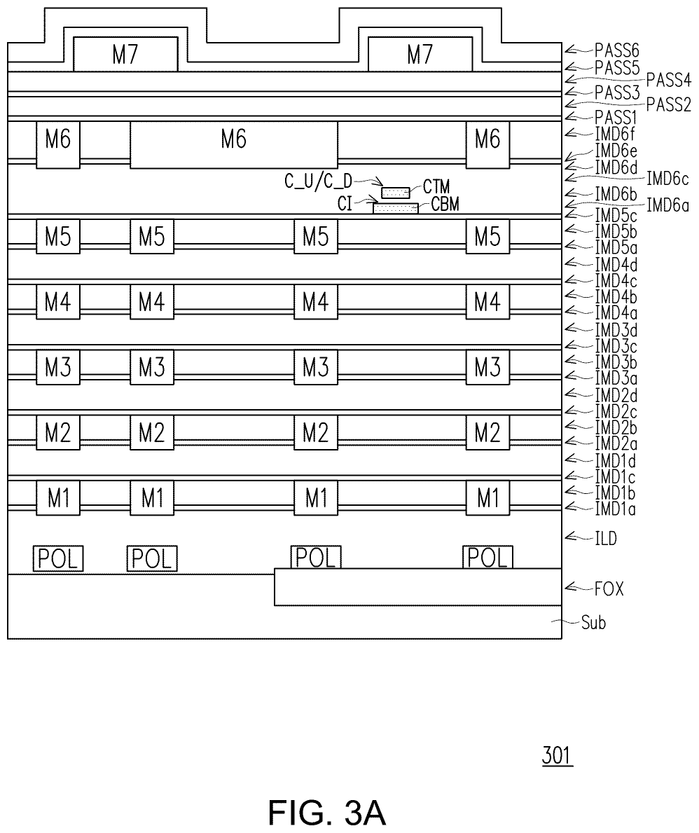

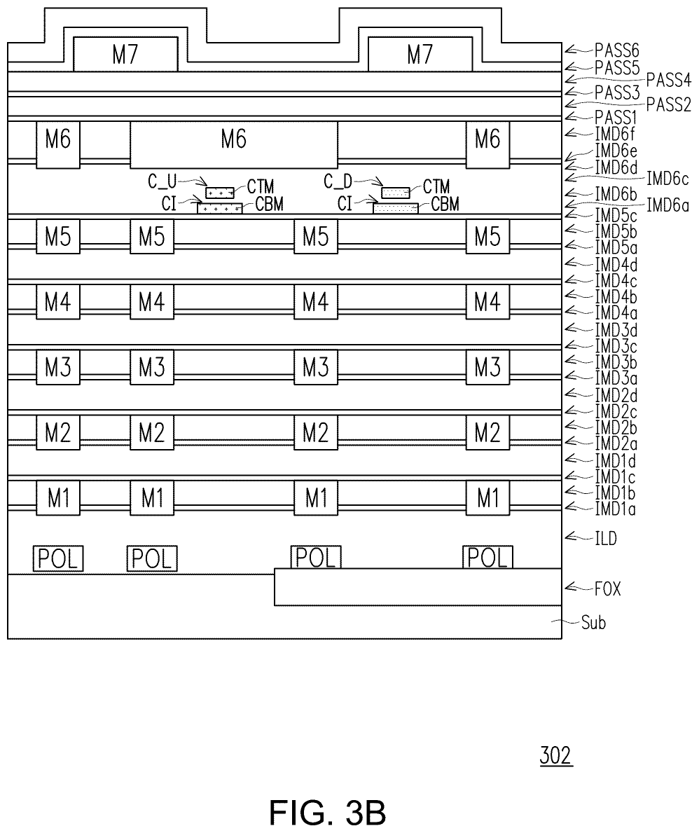

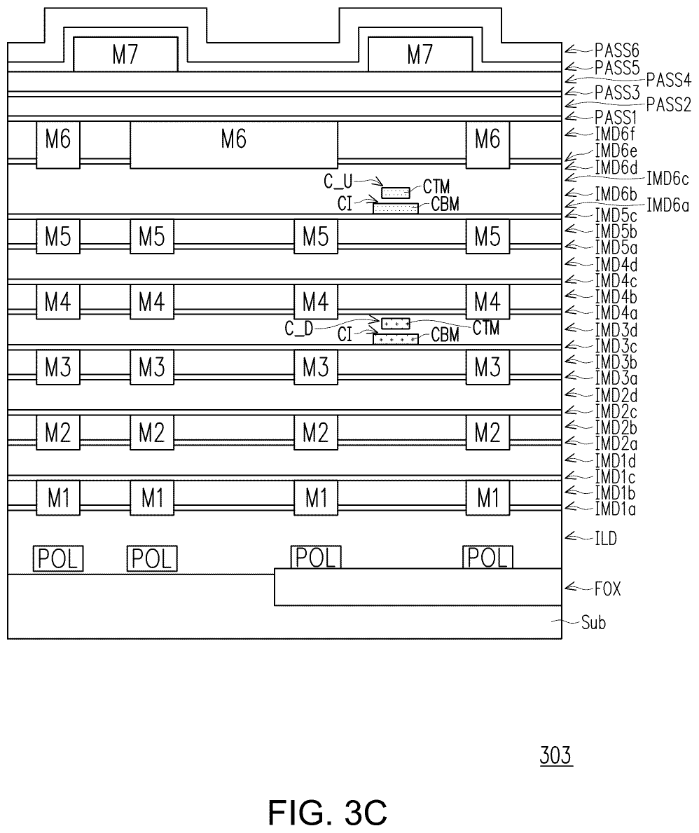

FIG. 3A is a schematic cross-section view of a MIM capacitor disposed on a substrate according to one embodiment of the disclosure.

Reference is made to FIG. 3A first. A cross-section view 301 depicts a semiconductor chip and the semiconductor chip may include a substrate Sub and a MIM capacitor disposed on the substrate Sub. The semiconductor chip may further include a back-end-of-line (BEOL) metallization stack above the substrate Sub and the MIM capacitor may be disposed in the metallization stack. In one embodiment, the metallization stack may include 7 tiers, from metal layer M1 to metal layer M7, a plurality of inter-metal dielectric layers IMD1a˜IMD6f between the metal layer M1 to the metal layer M7, and a plurality of passivation layers PASS1˜PASS7. Further, an inter-layer dielectric layer ILD, a plurality of polysilicon layer POL, and a field oxide layer FOX may be disposed between the metallization stack and the substrate Sub. Furthermore, the MIM capacitor may be disposed in the inter-metal dielectric layers IMD6a˜IMD6c corresponding to the metal layer M6. However, this disclosure is not limited thereto. The MIM capacitor may be the first MIM capacitor C_U or the second MIM capacitor C_D.

FIG. 3B and FIG. 3C are schematic cross-section views of two MIM capacitor disposed on a substrate according to two embodiments of the disclosure.

Reference is made to FIG. 3B first. The difference between a cross-section view 302 of FIG. 3B and the cross-section view 301 of FIG. 3A is that two MIM capacitors are disposed on the substrate Sub rather than just one MIM capacitor. Further, the two MIM capacitors may include one first MIM capacitor C_U and one second MIM capacitor C_D. Furthermore, both of the first MIM capacitor C_U and the second MIM capacitor C_D may be disposed in the same layers, for example, the inter-metal dielectric layers IMD6a˜IMD6c corresponding to the metal layer M6. However, this disclosure is not limited thereto. Moreover, the first MIM capacitor C_U and the second MIM capacitor C_D may be electrically coupled together to form the MIM capacitor structure as the third MIM capacitor C_M. In this manner, the signal distortion may be prevented.

Reference is made to FIG. 3C now. Similar as FIG. 3B, the difference between a cross-section view 303 of FIG. 3C and the cross-section view 301 of FIG. 3A is that two MIM capacitors are disposed on the substrate Sub rather than just one MIM capacitor. Further, the two MIM capacitors may include one first MIM capacitor C_U and one second MIM capacitor C_D. Furthermore, the first MIM capacitor C_U and the second MIM capacitor C_D may be disposed in the two different layers corresponding to different metal layers M1˜M7. For example, first MIM capacitor C_U may be disposed in the inter-metal dielectric layers IMD6a˜IMD6c corresponding to the metal layer M6 and the second MIM capacitor C_D may be disposed in the inter-metal dielectric layer IMD3d corresponding to the metal layer M3. However, this disclosure is not limited thereto. Moreover, the first MIM capacitor C_U and the second MIM capacitor C_D may be electrically coupled together to form the MIM capacitor structure as the third MIM capacitor C_M. In this manner, the signal distortion may be prevented.

It is noted that, a connection structure may be configured to electrically coupling the first MIM capacitor C_U and the second MIM capacitor C_P disposed on a same semiconductor chip in parallel or in series. In one embodiment, the connection structure may be an intra-chip connection, such as a via or a metal line. It is worth mentioned that, in order to form the via or the metal line, an additional photomask may be required.

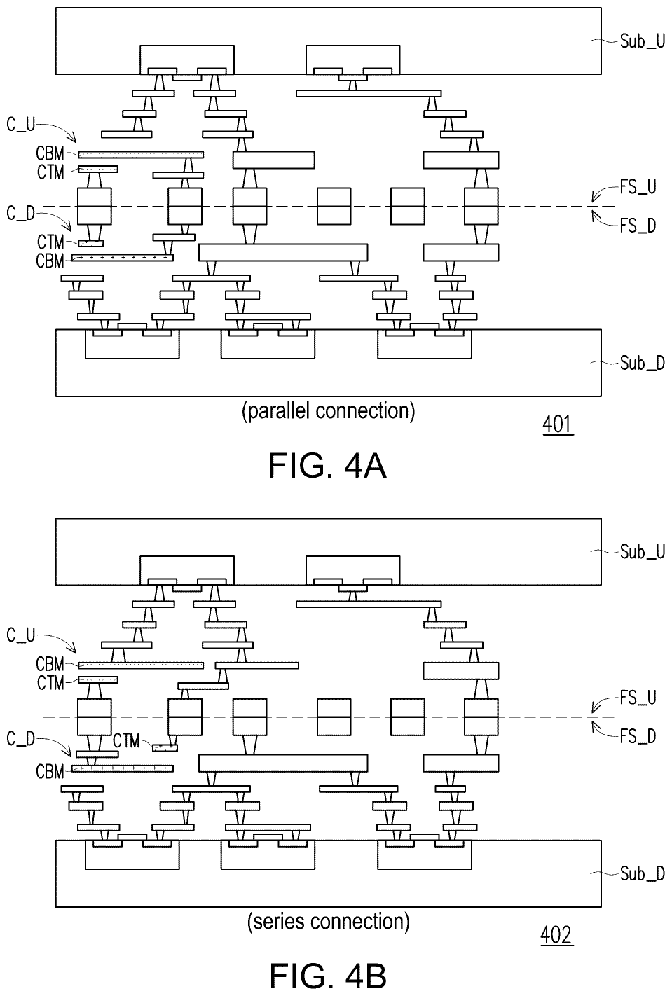

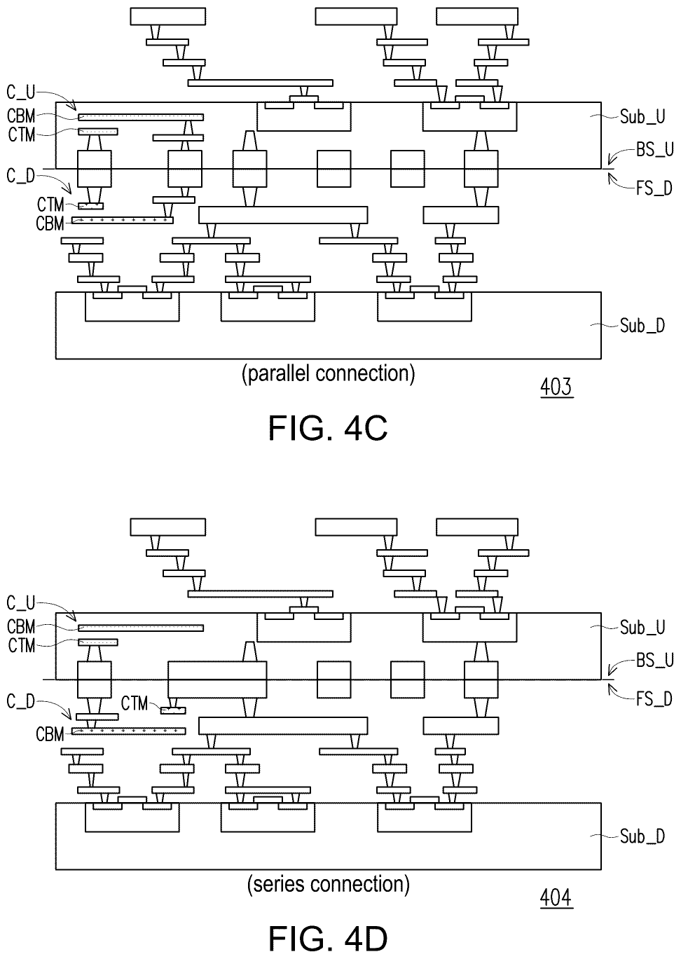

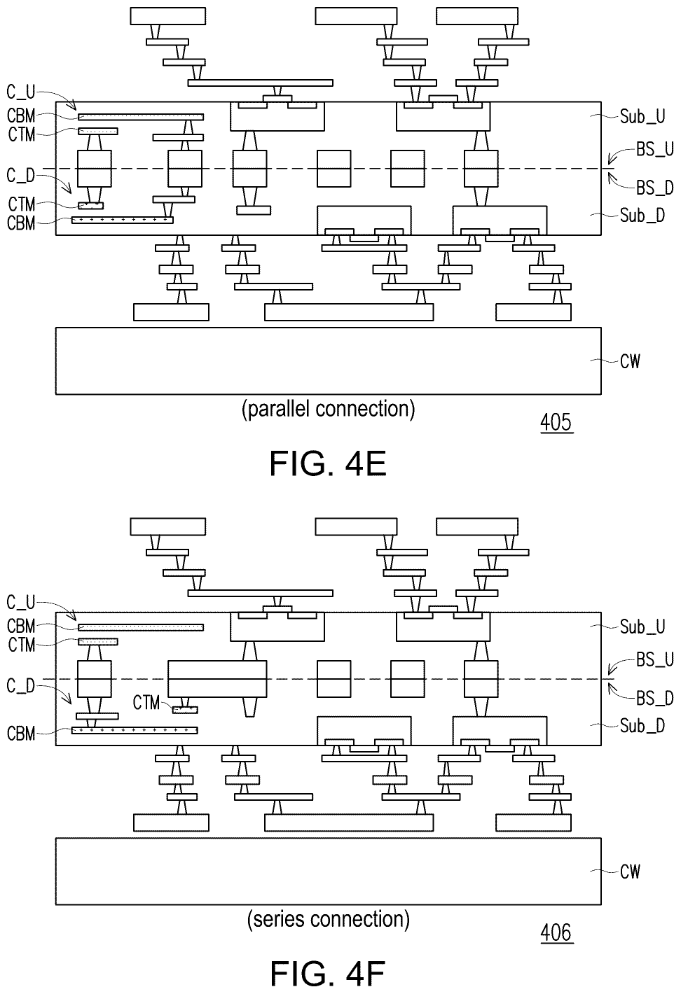

FIG. 4A to FIG. 4F are schematic cross-section views of two MIM capacitors disposed on two substrates according to some embodiment of the disclosure. In one embodiment, the two MIM capacitors may be the first MIM capacitor C_U and the second MIM capacitor C_D. Further, the first MIM capacitor C_U may be disposed on a first substrate Sub_U and the second MIM capacitor C_D may be disposed on a second substrate Sub_D. The first MIM capacitor C_U and the first substrate Sub_U may belong to a first semiconductor chip and the second MIM capacitor C_D and the second substrate Sub_D may belong to a second semiconductor chip.

With reference to FIG. 4A, a cross-section view 401 depicts that first semiconductor chip and the second semiconductor chip are bonding together (e.g., through hybrid bonding) and two front sides FS_U, FS_D of the two semiconductor chips are facing each other. Further, the top metal electrode CTM of the first MIM capacitor C_U and the top metal electrode CTM of the second MIM capacitor C_D may be electrically coupled together through the bonding. Furthermore, the bottom metal electrode CBM of the first MIM capacitor C_U and the bottom metal electrode CBM of the second MIM capacitor C_D may be electrically coupled together through the bonding. That is, the first MIM capacitor C_U and the second MIM capacitor C_D are electrically coupled in parallel.

With reference to FIG. 4B, a cross-section view 402 depicts that first semiconductor chip and the second semiconductor chip are bonding together (e.g., through hybrid bonding) and two front sides FS_U, FS_D of the two semiconductor chips are facing each other. Further, the top metal electrode CTM of the first MIM capacitor C_U and the top metal electrode CTM of the second MIM capacitor C_D may be electrically coupled together through the bonding. Furthermore, the bottom metal electrode CBM of the first MIM capacitor C_U and the bottom metal electrode CBM of the second MIM capacitor C_D may be electrically coupled to a bias voltage and a ground voltage respectively. That is, the first MIM capacitor C_U and the second MIM capacitor C_D are electrically coupled in series.

With reference to FIG. 4C, a cross-section view 403 depicts that first semiconductor chip and the second semiconductor chip are bonding together (e.g., through hybrid bonding) and a back side BS_U of the first semiconductor chip is facing the front side FS_D of the second semiconductor chip. Further, the top metal electrode CTM of the first MIM capacitor C_U and the top metal electrode CTM of the second MIM capacitor C_D may be electrically coupled together through the bonding. Furthermore, the bottom metal electrode CBM of the first MIM capacitor C_U and the bottom metal electrode CBM of the second MIM capacitor C_D may be electrically coupled together through the bonding. That is, the first MIM capacitor C_U and the second MIM capacitor C_D are electrically coupled in parallel.

With reference to FIG. 4D, a cross-section view 404 depicts that first semiconductor chip and the second semiconductor chip are bonding together (e.g., through hybrid bonding) and a back side BS_U of the first semiconductor chip is facing the front side FS_D of the second semiconductor chip. Further, the top metal electrode CTM of the first MIM capacitor C_U and the top metal electrode CTM of the second MIM capacitor C_D may be electrically coupled together through the bonding. Furthermore, the bottom metal electrode CBM of the first MIM capacitor C_U and the bottom metal electrode CBM of the second MIM capacitor C_D may be electrically coupled to a bias voltage and a ground voltage respectively. That is, the first MIM capacitor C_U and the second MIM capacitor C_D are electrically coupled in series.

With reference to FIG. 4E, a cross-section view 405 depicts that first semiconductor chip and the second semiconductor chip are bonding together (e.g., through hybrid bonding) and two back sides BS_U, BS_D of the two semiconductor chips are facing each other. Further, the top metal electrode CTM of the first MIM capacitor C_U and the top metal electrode CTM of the second MIM capacitor C_D may be electrically coupled together through the bonding. Furthermore, the bottom metal electrode CBM of the first MIM capacitor C_U and the bottom metal electrode CBM of the second MIM capacitor C_D may be electrically coupled together through the bonding. That is, the first MIM capacitor C_U and the second MIM capacitor C_D are electrically coupled in parallel.

With reference to FIG. 4F, a cross-section view 406 depicts that first semiconductor chip and the second semiconductor chip are bonding together (e.g., through hybrid bonding) and two back sides BS_U, BS_D of the two semiconductor chips are facing each other. Further, the top metal electrode CTM of the first MIM capacitor C_U and the top metal electrode CTM of the second MIM capacitor C_D may be electrically coupled together through the bonding. Furthermore, the bottom metal electrode CBM of the first MIM capacitor C_U and the bottom metal electrode CBM of the second MIM capacitor C_D may be electrically coupled to a bias voltage and a ground voltage respectively. That is, the first MIM capacitor C_U and the second MIM capacitor C_D are electrically coupled in series.

Reference is now made to FIG. 4A to FIG. 4F together. It is noted that, a connection structure may be configured to electrically coupling the first MIM capacitor C_U and the second MIM capacitor C_P disposed on two semiconductor chips in parallel or in series. That is, the first semiconductor chip and the second semiconductor chip may be coupled together to form an integrated chip. In these embodiments, because the first MIM capacitor C_U and the second MIM capacitor C_D are electrically coupled together through an inter-chip connection (i.e., a bonding process), no additional photomask may be required for connecting the first MIM capacitor C_U to the second MIM capacitor C_D. Therefore, the cost may be decreased since the cost of one photomask is much more expensive than a bonding process. For example, the MIM capacitor disposed on one semiconductor chip in FIG. 3A to FIG. 3C may be electrically coupled to another MIM capacitor without an additional mask. In this manner, the signal distortion may be prevented and the cost may be decreased at the same time.

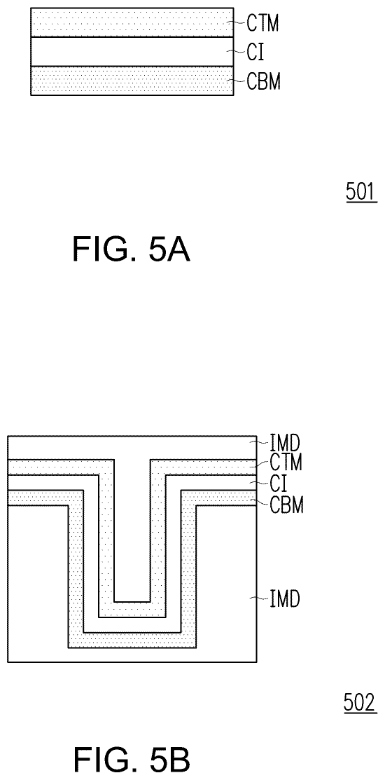

FIG. 5A to FIG. 5B are schematic cross-section views of a MIM capacitor according to two embodiments of the disclosure.

With reference to FIG. 5A and FIG. 5B, a cross-section view 501 depicts a planar MIM structure and a cross-section view 502 depicts a 3D MIM trench structure. Each of these MIM capacitor structures may both include the top metal electrode CTM and the bottom metal electrode CBM on either side of the capacitor insulator (also may be call the capacitor dielectric). For the 3D MIM trench structure, some inter-metal dielectric layers IMD may be formed around the MIM capacitor. That is, according to design needs, the first MIM capacitor C_U and the second MIM capacitor C_D may be planar capacitors, or the first MIM capacitor C_U and the second MIM capacitor C_D may be 3D capacitors It is noted that, a capacitance of a MIM capacitor may be determined based on the geometries of the top metal electrode CTM and the bottom metal electrode CBM and the property of the dielectric material of the insulator CI. Because the 3D MIM trench structure may have more areas between the top metal electrode CTM and the bottom metal electrode CBM, the 3D MIM trench structure may have a higher capacitance than the planar MIM structure. In one embodiment, the capacitance of the 3D MIM trench structure may be at least 3 times of the capacitance of planar MIM structure. That is, while the capacitance is not enough for a design need, the 3D MIM trench structure may be utilized, thereby increasing the density of capacitance and expanding an applicability of the MIM capacitor.

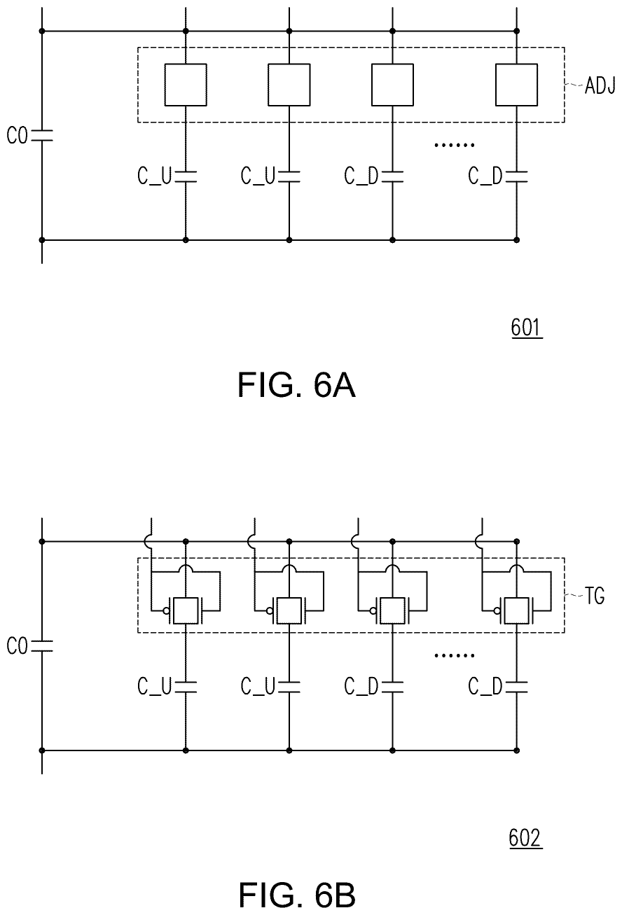

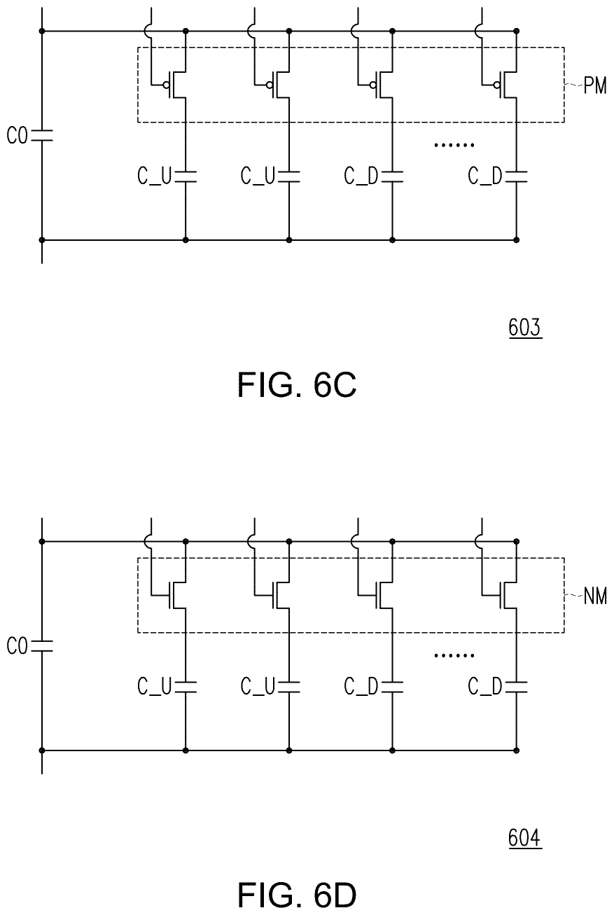

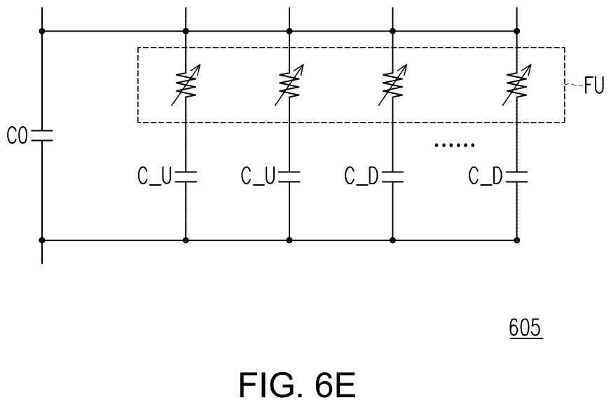

FIG. 6A to FIG. 6E are schematic layouts of a MIM capacitor circuit according to some embodiments of the disclosure.

Reference is first made to FIG. 6A. A MIM capacitor circuit 601 may include an original MIM capacitor C0, at least one first MIM capacitor C_U, at least one second MIM capacitor C_D, and at least one adjustment component ADJ. The original MIM capacitor C0, the first MIM capacitor C_U, and the second MIM capacitor C_D may be electrically coupled in parallel. The adjustment component ADJ may be electrically coupled between the original capacitor C0 and the first MIM capacitor C_U or between the original capacitor C0 and the second MIM capacitor C_D.

It is worth mentioned that, original MIM capacitor C0 may be implemented using the third capacitor C_M to prevent the signal distortion. That is, the original MIM capacitor C0 may include the first MIM capacitor C_U and the second MIM capacitor C_D. However, due to manufacture parameters or environment parameters, a capacitance of the third MIM capacitor C_M may be slightly different from an ideal capacitance. Traditionally, a capacitance of a capacitor circuit is unable to be modified after the fabrication process. In this disclosure, the adjustment component ADJ is utilized to adjust a capacitance of the MIM capacitor circuit 601.

For example, the adjustment component ADJ may be configured to couple the first MIM capacitor C_U or the second MIM capacitor C_D to the original MIM capacitor C0 based on an adjustment signal (not shown). By coupling the first MIM capacitor C_U or the second MIM capacitor C_D to the original MIM capacitor C0, a capacitance of the original MIM capacitor C0 may be still the same, but a total capacitance of the MIM capacitor circuit 601 may be adjusted. That is, the adjustment component ADJ may be configured to adjust the total capacitance of the MIM capacitor circuit 601. In one embodiment, by coupling the first MIM capacitor C_U to the original MIM capacitor, a capacitance-voltage characteristic of the MIM capacitor circuit 601 may be adjusted towards a capacitance-voltage characteristic of the first MIM capacitor C_U (i.e., increasing the voltage coefficient of capacitance). In another embodiment, by coupling the second MIM capacitor C_D to the original MIM capacitor, a capacitance-voltage characteristic of the MIM capacitor circuit 601 may be adjusted towards a capacitance-voltage characteristic of the second MIM capacitor C_D (i.e., decreasing the voltage coefficient of capacitance). In this manner, even after the fabrication process, a total capacitance of the MIM capacitor circuit 601 may be still adjustable, thereby expanding an applicability of the MIM capacitor circuit 601.

Reference is now made to FIG. 6B. A MIM capacitor circuit 602 may be one exemplary embodiment of the MIM capacitor circuit 601. In this embodiment, the adjustment component ADJ may be implemented using a transmission gate TG. The transmission gate TG may be configured to be enabled or disabled to couple the first MIM capacitor C_U or the second MIM capacitor C_D to the original MIM capacitor C0 according to design needs.

Reference is now made to FIG. 6C. A MIM capacitor circuit 603 may be another exemplary embodiment of the MIM capacitor circuit 601. In this embodiment, the adjustment component ADJ may be implemented using a P-type metal-oxide-semiconductor field-effect transistor (PMOSFET) PM. The PMOSFET PM may be configured to be enabled or disabled to couple the first MIM capacitor C_U or the second MIM capacitor C_D to the original MIM capacitor C0 according to design needs.

Reference is now made to FIG. 6D. A MIM capacitor circuit 604 may be yet another exemplary embodiment of the MIM capacitor circuit 601. In this embodiment, the adjustment component ADJ may be implemented using a N-type metal-oxide-semiconductor field-effect transistor (NMOSFET) NM. The NMOSFET PM may be configured to be enabled or disabled to couple the first MIM capacitor C_U or the second MIM capacitor C_D to the original MIM capacitor C0 according to design needs.

Reference is now made to FIG. 6E. A MIM capacitor circuit 605 may be an additional exemplary embodiment of the MIM capacitor circuit 601. In this embodiment, the adjustment component ADJ may be implemented using a fuse FU. After the fabrication process, at least one fuse FU may be configured to couple the first MIM capacitor C_U and/or the second MIM capacitor C_D to the original MIM capacitor C0. Further, the fuse may be configured to be blow to decouple the first MIM capacitor C_U or the second MIM capacitor C_D to the original MIM capacitor C0 according to design needs.

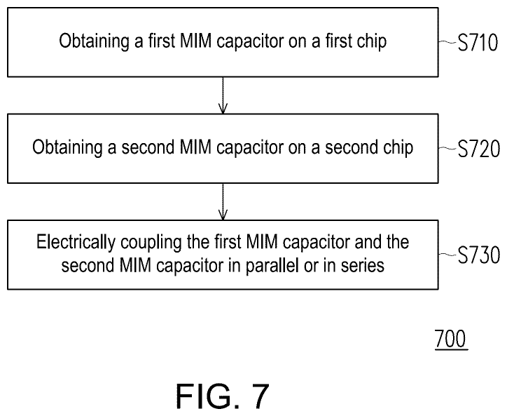

FIG. 7 is a schematic flowchart of a method for forming a MIM capacitor structure according to some embodiments of the disclosure.

With reference to FIG. 7, a method 700 for forming a MIM capacitor structure may include a step S710, a step S720, and a step S730. In the step S710, the first MIM capacitor C_U may be obtained and the first MIM capacitor C_U may be disposed on a first (semiconductor) chip. In the step S720, the second MIM capacitor C_D may be obtained and the second MIM capacitor C_D may be disposed on a second (semiconductor) chip. In the step S730, the first MIM capacitor C_U and the second MIM capacitor C_D maybe electrically coupled together in parallel or in series through the connection structure to form the MIM capacitor structure as the third MIM capacitor C_M. In this manner, the MIM capacitor structure may be formed and the distortion of the signal may be prevented.

In addition, the implementation details of the method 700 may be referred to the descriptions of FIG. 1 to FIG. 6E to obtain sufficient teachings, suggestions, and implementation embodiments, while the details are not redundantly described seriatim herein.

In summary, according to the MIM capacitor structure, the integrated circuit, and the method for forming the MIM capacitor structure, a voltage-capacitance characteristic of a MIM capacitor structure may be adjusted by merging the first MIM capacitor C_U and the second MIM capacitor C_D. Therefore, the distortion of the signal may be prevented.

In one aspect of this disclosure, this disclosure provides a Metal-Insulator-Metal (MIM) capacitor structure. The MIM capacitor structure includes a first MIM capacitor, a second MIM capacitor, and a connection structure. In response to an increment of a positive bias voltage, a first capacitance of the first MIM capacitor increases. In response to the increment of the positive bias voltage, a second capacitance of the second MIM capacitor decreases. The connection structure is configured to electrically couple the first MIM capacitor and the second MIM capacitor in parallel or in series.

In a related embodiment, in response to the increment of the positive bias voltage, a total capacitance of the MIM capacitor structure substantially remains a fixed value.

In a related embodiment, the first MIM capacitor includes a first top metal electrode, a first bottom metal electrode, and a first capacitor dielectric. The first capacitor dielectric is disposed between the first tope metal electrode and the first bottom metal electrode. The first dielectric comprises silicon nitride, zirconium oxide, hafnium oxide, aluminum oxide, or zirconium trioxide. The MIM capacitor includes a second top metal electrode, a second bottom metal electrode, and a second capacitor dielectric. The second capacitor dielectric is disposed between the second tope metal electrode and the second bottom metal electrode. The second dielectric comprises silicon oxide, or barium titanium oxide.

In a related embodiment, the first MIM capacitor and the second MIM capacitor are disposed on a same semiconductor chip, and the connection structure comprises an intra-chip connection.

In a related embodiment, the first MIM capacitor and the second MIM capacitor are disposed on two first semiconductor chips, and the connection structure comprises an inter-chip connection.

In a related embodiment, the first MIM capacitor and the second MIM capacitor are planar capacitors.

In a related embodiment, the first MIM capacitor and the second MIM capacitor are 3D capacitors.

In a related embodiment, the MIM capacitor structure further includes an adjustment component. The adjustment component is configured to adjust a total capacitance of the MIM capacitor.

In another aspect of this disclosure, this disclosure provides an integrated chip. The integrated chip includes a first semiconductor chip, a second semiconductor chip, and a connection structure. The first semiconductor chip includes a first substrate, and a first metallization stack. The firs metallization stack is disposed on the first substrate and includes a first MIM capacitor. In response to an increment of a positive bias voltage, a first capacitance of the first MIM capacitor increases. The second semiconductor chip includes a second substrate, and a second metallization stack. The second metallization stack is disposed on the second substrate and includes a second MIM capacitor. In response to the increment of the positive bias voltage, a second capacitance of the second MIM capacitor decreases. The connection structure is configured to electrically couple the first MIM capacitor and the second MIM capacitor in parallel or in series.

In a related embodiment, the first metallization stack is disposed on a front side of the first semiconductor chip, the second metallization stack is disposed on a front side of the second semiconductor chip, and the first MIM capacitor and the second MIM capacitor are electrically coupled in parallel.

In a related embodiment, the first metallization stack is disposed on a front side of the first semiconductor chip, the second metallization stack is disposed on a front side of the second semiconductor chip, and the first MIM capacitor and the second MIM capacitor are electrically coupled in series.

In a related embodiment, the first metallization stack is disposed on a back side of the first semiconductor chip, the second metallization stack is disposed on a front side of the second semiconductor chip, and the first MIM capacitor and the second MIM capacitor are electrically coupled in parallel.

In a related embodiment, the first metallization stack is disposed on a back side of the first semiconductor chip, the second metallization stack is disposed on a front side of the second semiconductor chip, and the first MIM capacitor and the second MIM capacitor are electrically coupled in series.

In a related embodiment, the first metallization stack is disposed on a back side of the first semiconductor chip, the second metallization stack is disposed on a back side of the second semiconductor chip, and the first MIM capacitor and the second MIM capacitor are electrically coupled in parallel.

In a related embodiment, the first metallization stack is disposed on a back side of the first semiconductor chip, the second metallization stack is disposed on a back side of the second semiconductor chip, and the first MIM capacitor and the second MIM capacitor are electrically coupled in series.

In a related embodiment, a first bottom metal electrode of the first MIM capacitor has a larger footprint than a first top metal electrode of the first MIM capacitor, and a second bottom metal electrode of the second MIM capacitor has a larger footprint than a second top metal electrode of the second MIM capacitor.

In yet another aspect of this disclosure, this disclosure provides a method for forming a MIM capacitor structure. The method includes: obtaining a first MIM capacitor on a first semiconductor chip, wherein in response to an increment of a positive bias voltage, a first capacitance of the first MIM capacitor increases; obtaining a second MIM capacitor on a second semiconductor chip, wherein in response to the increment of the positive bias voltage, a second capacitance of the second MIM capacitor decreases; and electrically coupling the first MIM capacitor and the second MIM capacitor in parallel or in series.

In a related embodiment, in response to the increment of the positive bias voltage, a total capacitance of the MIM capacitor structure substantially remains a fixed value.

In a related embodiment, the first MIM capacitor and the second MIM capacitor are planar capacitors.

In a related embodiment, the first MIM capacitor and the second MIM capacitor are 3D capacitors.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A Metal-Insulator-Metal (MIM) capacitor structure, comprising:
a first MIM capacitor, wherein in response to an increment of a positive bias voltage, a first capacitance of the first MIM capacitor increases;
a second MIM capacitor, wherein in response to the increment of the positive bias voltage, a second capacitance of the second MIM capacitor decreases; and
a connection structure, electrically coupling the first MIM capacitor and the second MIM capacitor in parallel or in series.

2. The MIM capacitor structure according to claim 1, wherein in response to the increment of the positive bias voltage, a total capacitance of the MIM capacitor structure substantially remains a fixed value.

3. The MIM capacitor structure according to claim 1, wherein
the first MIM capacitor comprises:
a first top metal electrode;
a first bottom metal electrode; and
a first capacitor dielectric, disposed between the first tope metal electrode and the first bottom metal electrode, wherein the first dielectric comprises silicon nitride, zirconium oxide, hafnium oxide, aluminum oxide, or zirconium trioxide, and
the second MIM capacitor comprises:
a second top metal electrode;
a second bottom metal electrode; and
a second capacitor dielectric, disposed between the second tope metal electrode and the second bottom metal electrode, wherein the second dielectric comprises silicon oxide, or barium titanium oxide.

4. The MIM capacitor structure according to claim 1, wherein
the first MIM capacitor and the second MIM capacitor are disposed on a same semiconductor chip, and
the connection structure comprises an intra-chip connection.

5. The MIM capacitor structure according to claim 1, wherein
the first MIM capacitor and the second MIM capacitor are disposed on two semiconductor chips, and
the connection structure comprises an inter-chip connection.

6. The MIM capacitor structure according to claim 1, wherein the first MIM capacitor and the second MIM capacitor are planar capacitors.

7. The MIM capacitor structure according to claim 1, wherein the first MIM capacitor and the second MIM capacitor are 3D capacitors.

8. The MIM capacitor structure according to claim 1, further comprising:
an adjustment component, configured to adjust a total capacitance of the MIM capacitor.

9. An integrated chip, comprising:
a first semiconductor chip, comprising:
a first substrate; and
a first metallization stack, disposed on the first substrate and comprising a first MIM capacitor, wherein in response to an increment of a positive bias voltage, a first capacitance of the first MIM capacitor increases;
a second semiconductor chip, comprising:
a second substrate; and
a second metallization stack, disposed on the second substrate and comprising a second MIM capacitor, wherein in response to the increment of the positive bias voltage, a second capacitance of the second MIM capacitor decreases; and
a connection structure, electrically coupling the first MIM capacitor and the second MIM capacitor in parallel or in series.

10. The integrated chip according to claim 9, wherein
the first metallization stack is disposed on a front side of the first semiconductor chip,
the second metallization stack is disposed on a front side of the second semiconductor chip, and
the first MIM capacitor and the second MIM capacitor are electrically coupled in parallel.

11. The integrated chip according to claim 9, wherein
the first metallization stack is disposed on a front side of the first semiconductor chip,
the second metallization stack is disposed on a front side of the second semiconductor chip, and
the first MIM capacitor and the second MIM capacitor are electrically coupled in series.

12. The integrated chip according to claim 9, wherein
the first metallization stack is disposed on a back side of the first semiconductor chip,
the second metallization stack is disposed on a front side of the second semiconductor chip, and
the first MIM capacitor and the second MIM capacitor are electrically coupled in parallel.

13. The integrated chip according to claim 9, wherein
the first metallization stack is disposed on a back side of the first semiconductor chip,
the second metallization stack is disposed on a front side of the second semiconductor chip, and
the first MIM capacitor and the second MIM capacitor are electrically coupled in series.

14. The integrated chip according to claim 9, wherein
the first metallization stack is disposed on a back side of the first semiconductor chip,
the second metallization stack is disposed on a back side of the second semiconductor chip, and
the first MIM capacitor and the second MIM capacitor are electrically coupled in parallel.

15. The integrated chip according to claim 9, wherein
the first metallization stack is disposed on a back side of the first semiconductor chip,
the second metallization stack is disposed on a back side of the second semiconductor chip, and
the first MIM capacitor and the second MIM capacitor are electrically coupled in series.

16. The integrated chip according to claim 9, wherein
a first bottom metal electrode of the first MIM capacitor has a larger footprint than a first top metal electrode of the first MIM capacitor, and
a second bottom metal electrode of the second MIM capacitor has a larger footprint than a second top metal electrode of the second MIM capacitor.

17. A method for forming a MIM capacitor structure, comprising:
obtaining a first MIM capacitor on a first semiconductor chip, wherein in response to an increment of a positive bias voltage, a first capacitance of the first MIM capacitor increases;
obtaining a second MIM capacitor on a second semiconductor chip, wherein in response to the increment of the positive bias voltage, a second capacitance of the second MIM capacitor decreases; and
electrically coupling the first MIM capacitor and the second MIM capacitor in parallel or in series.

18. The method according to claim 17, wherein in response to the increment of the positive bias voltage, a total capacitance of the MIM capacitor structure substantially remains a fixed value.

19. The method according to claim 17, wherein the first MIM capacitor and the second MIM capacitor are planar capacitors.

20. The method according to claim 17, wherein the first MIM capacitor and the second MIM capacitor are 3D capacitors.
